(19) United States
(12) Patent Application Publication
(10) Pub. No.: US 2026/0286119 A1
(43) Pub. Date: Sep. 24, 2026

(54) RESIN COMPOSITION, PREPREG, LAMINATE, RESIN FILM, PRINTED WIRING BOARD, AND SEMI-CONDUCTOR PACKAGE

(71) Applicant: Resonac Corporation, Minato-ku, Tokyo (JP)

(72) Inventors: Ren SASAKI, Minato-ku, Tokyo (JP); Tano RYOSUKE, Minato-ku, Tokyo (JP); Yoshikatsu SHIRAOKAWA, Minato-ku, Tokyo (JP)

(21) Appl. No.: 19/475,837

(22) PCT Filed: Dec. 5, 2024
(86) PCT No.: PCT/JP2024/043101

§ 371 Date: Oct. 16, 2025

(30) Foreign Application Priority Data
Dec. 12, 2023 (JP) 2023-209057

(51) Int. Cl. C08L 35/00; B32B 15/08; C08K 3/016; C08K 3/32; C08K 3/36; H05K 1/03

(52) U.S. Cl. CPC C08L 35/00; B32B 15/08; C08K 3/016; C08K 3/32; C08K 3/36; H05K 1/0373; B32B 2250/02; B32B 2307/3065; B32B 2457/08; C08K 2003/329; H05K 2201/012; H05K 2201/0162; H05K 2201/0209

(57) ABSTRACT

Provided are a resin composition containing: (A) a siloxane-modified maleimide resin containing a structure derived from a maleimide resin having one or more N-substituted maleimide groups (A1) and a structure derived from a siloxane compound having two or more primary amino groups (A2); (B) a polyphenylene ether-based resin having a functional group containing an ethylenically unsaturated bond; and (C) a phosphorus-based flame retardant containing a phosphorus atom in a content of 12 mass % or more, and a prepreg, a laminate, a resin film, a printed wiring board, and a semiconductor package in which the resin composition is used.

### TECHNICAL FIELD

The present embodiment relates to a resin composition, a prepreg, a laminate, a resin film, a printed wiring board, and a semiconductor package.

### BACKGROUND ART

In electronic devices, such as a mobile communication device represented by a mobile phone, a base station device thereof, network infrastructure devices, such as a server and a router, and a large computer, the speed and the capacity of a signal to be used are increasing year by year. Accordingly, dielectric characteristics in which transmission loss of a high-frequency signal can be reduced are required for a substrate material of a printed wiring board to be mounted on these electronic devices.

In PTL 1, in order to provide a curable resin composition having low dielectric constant and dielectric loss tangent of a cured product to be obtained, and excellent heat resistance as a resin composition applicable to an insulating layer of a printed wiring board, a curable resin composition containing a naphthol novolac type epoxy resin and a polyphenylene ether resin is disclosed.

### CITATION LIST

### Patent Literature

PTL 1: JP 2013-185080 A

### SUMMARY OF INVENTION

### Technical Problem

Excellent flame resistance is required for an insulating material, such as a prepreg.

However, when a flame retardant is added to a resin composition to improve flame resistance, there is a problem in that the embedding properties of a circuit are deteriorated. Examples of a method for improving the circuit embedding properties include a method for reducing the viscosity of a resin composition with which a prepreg is impregnated. However, the method for simply reducing the viscosity of a resin composition causes a problem in that resin flow occurs in which the molten resin composition flows from an end in press-molding a prepreg or the like, and the thickness precision of a molded product is reduced.

In view of such a current situation, an object of the present embodiment is to provide a resin composition containing a flame retardant and having excellent circuit embedding properties with resin flow being satisfactorily suppressed, a prepreg, a laminate, a resin film, a printed wiring board, and a semiconductor package in which the resin composition is used.

### Solution to Problem

The present inventors have intensively studied to solve the problems, and as a result, found that the following embodiments can solve the problems.
[1] A resin composition containing:
(A) a siloxane-modified maleimide resin containing a structure derived from a maleimide resin having one or more N-substituted maleimide groups (A1) and a structure derived from a siloxane compound having two or more primary amino groups (A2);
(B) a polyphenylene ether-based resin having a functional group containing an ethylenically unsaturated bond; and
(C) a phosphorus-based flame retardant containing a phosphorus atom in a content of 12 mass % or more.
[2] The resin composition according to [1], in which the component (C) is a metal salt of phosphoric acid.
[3] The resin composition according to [1] or [2], in which a content of the component (C) is 1 to 30 parts by mass with respect to a total amount (100 parts by mass) of a resin component in the resin composition.
[4] The resin composition according to any one of [1] to [3], in which the component (B) has the functional group containing an ethylenically unsaturated bond at an end thereof.
[5] The resin composition according to any one of [1] to [4], in which the functional group containing an ethylenically unsaturated bond of the component (B) is a (meth)acryloyl group.
[6] The resin composition according to any one of [1] to [5], further containing (D) an inorganic filler.
[7] The resin composition according to [6], in which a content of the component (D) is 20 to 90 mass % with respect to a total amount (100 mass %) of a solid content in the resin composition.
[8] A prepreg containing the resin composition according to any one of [1] to [7] or a semi-cured product of the resin composition.
[9] A laminate including: a cured product of the resin composition according to any one of [1] to [7]; and a metal foil.
[10] A resin film containing the resin composition according to any one of [1] to [7] or a semi-cured product of the resin composition.
[11] A printed wiring board including a cured product of the resin composition according to any one of [1] to [7].
[12] A semiconductor package including: the printed wiring board according to [11]; and a semiconductor element.

### Advantageous Effects of Invention

The present embodiment can provide a resin composition containing a flame retardant and having excellent circuit embedding properties with resin flow being satisfactorily suppressed, a prepreg, a laminate, a resin film, a printed wiring board, and a semiconductor package in which the resin composition is used.

### DESCRIPTION OF EMBODIMENTS

In the present description, a numerical range indicated by using “to” indicates a range including numerical values described before and after “to” as a minimum value and a maximum value, respectively.

For example, the expression of the numerical value range of “X to Y” (X and Y are real numbers) means the numerical value range of X or more and Y or less. In the present description, “X or more” means X and a numerical value more than X. In the present description, “Y or less” means Y and a numerical value less than Y The lower limit value and the upper limit value of a numerical value range described herein are each optionally combined with the lower limit value or the upper limit value of another numerical value range.

In a numerical range described in the present description, the lower limit value or the upper limit value of the numerical range may be replaced with a value shown in Examples.

Each component and material exemplified in the present description may be used alone or may be used in combination of two or more kinds thereof, unless particularly otherwise specified.

In the present description, when a plurality of substances corresponding to components are present in a resin composition, the content of each of the components in the resin composition means the total amount of the plurality of substances present in the resin composition, unless particularly otherwise specified.

The expression “containing XX” described in the present description includes the meaning in which XX is contained in a reacted state when XX can react, and the meaning in which XX is simply contained.

In the present description, a “solid content” means a component other than a solvent, and a component in a liquid state at 25° C. is also regarded as the solid content.

In the present description, a “(meth)acryloyl” means “acryloyl” and “methacryloyl” corresponding to the acryloyl.

In the present description, a weight-average molecular weight (Mw) means a value measured in terms of polystyrene by gel permeation chromatography (GPC), and can be measured, specifically, by a method described in Examples.

The mechanism of action described in the present description is a conjecture, and does not limit the mechanism of achieving the effects of the present embodiment.

Aspects in which the matters described in the present description are optionally combined are also included in the present embodiment.

### [Resin Composition]

A resin composition of the present embodiment contains (A) a siloxane-modified maleimide resin containing a structure derived from a maleimide resin having one or more N-substituted maleimide groups (A1) and a structure derived from a siloxane compound having two or more primary amino groups (A2); (B) a polyphenylene ether-based resin having a functional group containing an ethylenically unsaturated bond; and (C) a phosphorus-based flame retardant containing a phosphorus atom in a content of 12 mass % or more.

In the following description, (A) the siloxane-modified maleimide resin containing a structure derived from a maleimide resin having one or more N-substituted maleimide groups (A1) and a structure derived from a siloxane compound having two or more primary amino groups (A2) is sometimes simply referred to as the “siloxane-modified maleimide resin (A).”

In addition, (B) the polyphenylene ether-based resin having a functional group containing an ethylenically unsaturated bond is sometimes referred to as “polyphenylene ether-based resin (B).”

Furthermore, (C) the phosphorus-based flame retardant containing a phosphorus atom in a content of 12 mass % or more is sometimes referred to as “phosphorus-based flame retardant (C).”

Moreover, the components are sometimes referred to as component (A), component (B), and the like.

Each of the components that can be contained in the resin composition of the present embodiment will be described below in turn.

### <Siloxane-modified Maleimide Resin (A)>

The siloxane-modified maleimide resin (A) contains a structure derived from a maleimide resin having one or more N-substituted maleimide groups (A1) (hereinafter also simply referred to as “maleimide resin (A1)”) and a structure derived from a siloxane compound having two or more primary amino groups (A2) (hereinafter also simply referred to as “siloxane compound (A2)”).

One kind of the siloxane-modified maleimide resin (A) may be used alone, or two or more kinds thereof may be used in combination.

The structure derived from the maleimide resin (A1) and the structure derived from the siloxane compound (A2) contained in the siloxane-modified maleimide resin (A) may each be of one kind or two or more kinds.

(Structure Derived from Maleimide Resin (A1))

Examples of the structure derived from the maleimide resin (A1) include structures obtained by a Michael addition reaction of at least one N-substituted maleimide group among the N-substituted maleimide groups of the maleimide resin (A1) with the primary amino groups of the siloxane compound (A2).

The content of the structure derived from the maleimide resin (A1) in the siloxane-modified maleimide resin (A) is not particularly limited, but from the viewpoint of dielectric characteristics and film handling properties, it is preferably 5 to 95 mass %, more preferably 30 to 93 mass %, and still more preferably 60 to 90 mass %.

The maleimide resin (A1) is not particularly limited as long as it is a maleimide resin having one or more N-substituted maleimide groups.

From the viewpoint of adhesion to conductors and heat resistance, the maleimide resin (A1) is preferably a maleimide resin having two or more N-substituted maleimide groups, more preferably an aromatic maleimide resin having two or more N-substituted maleimide groups, and still more preferably an aromatic bismaleimide resin having two N-substituted maleimide groups.

In the present description, the “aromatic maleimide resin” means a compound having an N-substituted maleimide group directly bonded to an aromatic ring. Further, in the present description, the “aromatic bismaleimide resin” means a compound having two N-substituted maleimide groups directly bonded to an aromatic ring.

Furthermore, in the present description, an “aromatic polymaleimide resin” means a compound having three or more N-substituted maleimide groups directly bonded to an aromatic ring.

Moreover, in the present description, an “aliphatic maleimide resin” means a compound having an N-substituted maleimide group directly bonded to an aliphatic hydrocarbon.

The maleimide resin (A1) is preferably a maleimide resin represented by the following general formula (A1-1) (hereinafter sometimes referred to as “maleimide resin (A1)”).

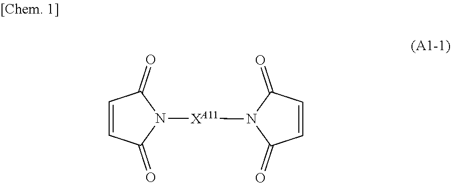

In the formula, X^{A11} is a divalent organic group.

X^{A11} in the general formula (A1-1) is a divalent organic group.

Examples of the divalent organic group represented by X^{A11} in the general formula (A1-1) include a divalent group represented by the following general formula (A1-2), a divalent group represented by the following general formula (A1-3), a divalent group represented by the following general formula (A1-4), a divalent group represented by the following general formula (A1-5), and a divalent group represented by the following general formula (A1-6).

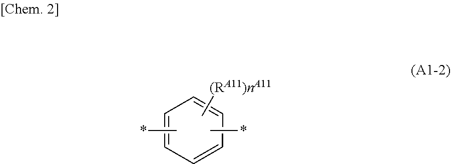

In the formula, R^{A11} is an aliphatic hydrocarbon group having 1 to 5 carbon atoms or a halogen atom; n^{A11} is an integer of 0 to 4; and * represents a binding site.

Examples of the aliphatic hydrocarbon group having 1 to 5 carbon atoms represented by R^{A11} in the general formula (A1-2) include alkyl groups having 1 to 5 carbon atoms, such as a methyl group, an ethyl group, an n-propyl group, an isopropyl group, an n-butyl group, an isobutyl group, a t-butyl group, and an n-pentyl group; an alkenyl group having 2 to 5 carbon atoms; and an alkynyl group having 2 to 5 carbon atoms. The aliphatic hydrocarbon groups having 1 to 5 carbon atoms may be either linear or branched.

Examples of the halogen atom include a fluorine atom, a chlorine atom, a bromine atom, and an iodine atom.

n^{A11} the general formula (A1-2) is an integer of 0 to 4. From the viewpoint of availability, n^{A11} is preferably an integer of 0 to 2, more preferably 0 or 1, and still more preferably 0. When n^{A11} is an integer of 2 or more, a plurality of R^{A11}'s may be the same as or different from each other.

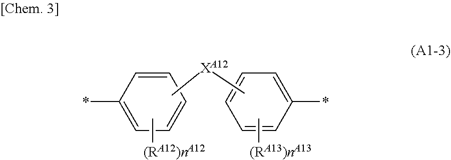

In the formula, R^{A12} and R^{A13} are each independently an aliphatic hydrocarbon group having 1 to 5 carbon atoms or a halogen atom; X^{A12} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent group represented by the following general formula (A1-3-1); n^{A12} and n^{A13} are each independently an integer of 0 to 4; and * represents a binding site.

Examples of the aliphatic hydrocarbon group having 1 to 5 carbon atoms and the halogen atom represented by R^{A12} and R^{A13} in the general formula (A1-3) are the same as the examples of the aliphatic hydrocarbon group having 1 to 5 carbon atoms and the halogen atom represented by R^{A11}.

Examples of the alkylene group having 1 to 5 carbon atoms represented by X^{A12} in the general formula (A1-3) include a methylene group, a 1,2-dimethylene group, a 1,3-trimethylene group, a 1,4-tetramethylene group, and a 1,5-pentamethylene group.

Examples of the alkylidene group having 2 to 5 carbon atoms represented by X^{A12} in the general formula (A1-3) include an ethylidene group, a propylidene group, an isopropylidene group, a butylidene group, an isobutylidene group, a pentylidene group, and an isopentylidene group.

n^{A12} and n^{A13} in the general formula (A1-3) are each independently an integer of 0 to 4. When n^{A12} or n^{A13} is an integer of 2 or more, a plurality of R^{A12}'s or a plurality of R^{A13}'s may be the same as or different from each other.

The divalent group represented by the general formula (A1-3-1) as X^{A12} in the general formula (A1-3) is as follows.

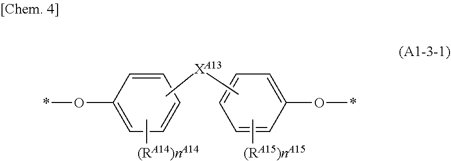

In the formula, R^{A14} and R^{A5} are each independently an aliphatic hydrocarbon group having 1 to 5 carbon atoms or a halogen atom; X^{A13} is an alkylene group having 1 to 5 carbon atoms, an alkylidene group having 2 to 5 carbon atoms, an ether group, a sulfide group, a sulfonyl group, a carbonyloxy group, a keto group, or a single bond. n^{A14} and n^{A15} are each independently an integer of 0 to 4; and * represents a binding site.

Examples of the aliphatic hydrocarbon group having 1 to 5 carbon atoms and the halogen atom represented by R^{A14} and R^{A15} in the general formula (A1-3-1) are the same as the examples of the aliphatic hydrocarbon group having 1 to 5 carbon atoms and the halogen atom represented by R^{A11}.

Examples of the alkylene group having 1 to 5 carbon atoms and the alkylidene group having 2 to 5 carbon atoms represented by X^{A13} in the general formula (A1-3-1) are the same as the examples of the alkylene group having 1 to 5 carbon atoms and the alkylidene group having 2 to 5 carbon atoms represented by X^{A12}. Among these, X^{A13} is preferably an alkylidene group having 2 to 5 carbon atoms, more preferably an alkylidene group having 2 to 4 carbon atoms, and still more preferably an isopropylidene group.

n^{A14} and n^{A15} in the general formula (A1-3-1) are each independently an integer of 0 to 4. From the viewpoint of availability, n^{A14} and n^{A15} are preferably an integer of 0 to 2, more preferably 0 or 1, and still more preferably 0. When n^{A14} or n^{A15} is an integer of 2 or more, a plurality of R^{A14}'s or a plurality of R^{A15}'s may be the same as or different from each other.

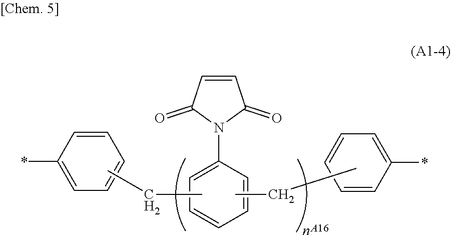

In the formula, n^{A16} is an integer of 0 to 10; and * represents a binding site.

n^{A16} in the general formula (A1-4) is preferably an integer of 0 to 5, more preferably an integer of 0 to 4, and still more preferably an integer of 0 to 3, from the viewpoint of availability.

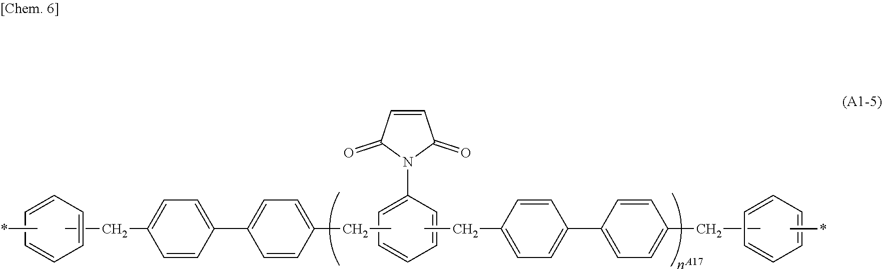

In the formula, n^{A17} is a number of 0 to 5; and * represents a binding site.

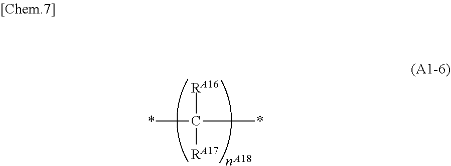

In the formula, R^{A16} and R^{A17} are each independently a hydrogen atom or an aliphatic hydrocarbon group having 1 to 5 carbon atoms; n^{A11} is an integer of 1 to 8; and * represents a binding site.

Examples of the aliphatic hydrocarbon group having 1 to 5 carbon atoms and the halogen atom represented by R^{A16} and R^{A17} in the general formula (A1-6) are the same as the examples of the aliphatic hydrocarbon group having 1 to 5 carbon atoms and the halogen atom represented by R^{A11}.

When n^{A11} is an integer of 2 or more, a plurality of R^{A16}'s or a plurality of R^{A17}'s may be the same as or different from each other.

Examples of the maleimide resin (A1) include an aromatic bismaleimide resin, an aromatic polymaleimide resin, and an aliphatic maleimide resin.

Examples of the maleimide resin (A1) include bis(4-maleimidophenyl)methane, m-phenylene bismaleimide, 2,2-bis[4-(4-maleimidophenoxy)phenyl]propane, 4-methyl-1,3-phenylene bismaleimide, 3,3′-dimethyl-5,5′-diethyl-4,4′-diphenylmethane bismaleimide, polyphenylmethane maleimide, biphenylaralkyl type maleimide, and an aromatic bismaleimide resin having an indan skeleton. Among these, 2,2-bis[4-(4-maleimidophenoxy)phenyl]propane is preferred.

(Structure Derived from Siloxane Compound (A2))

Examples of the structure derived from the siloxane compound (A2) include structures obtained by a Michael addition reaction of one or both of the two primary amino groups of the siloxane compound (A2) with the N-substituted maleimide groups of the maleimide resin (A1).

The content of the structure derived from the siloxane compound (A2) in the siloxane-modified maleimide resin (A) is not particularly limited, but is preferably 5 to 95 mass %, more preferably 7 to 70 mass %, and still more preferably 10 to 40 mass %, from the viewpoint of dielectric characteristics, heat resistance, flame resistance, and glass transition temperature.

The siloxane compound (A2) is not particularly limited as long as it is a siloxane compound having two or more primary amino groups.

The siloxane compound (A2) preferably contains a divalent group represented by the following general formula (A2-1), and more preferably contains a divalent group represented by the following general formula (A2-2).

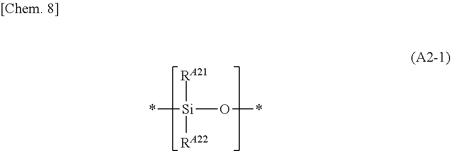

In the formula, R^{A21} and R^{A22} are each independently an aliphatic hydrocarbon group having 1 to 5 carbon atoms, a phenyl group, or a substituted phenyl group; and * represents a binding site.

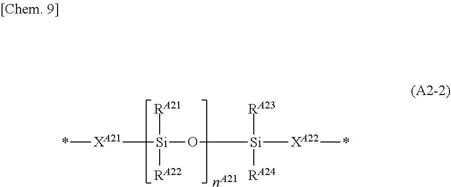

In the formula, R^{A21} and R^{A22} are the same as those in the general formula (A2-1); R^{A23} and R^{A24} are each independently an aliphatic hydrocarbon group having 1 to 5 carbon atoms, a phenyl group, or a substituted phenyl group; X^{A21} and X^{A22} are each independently a divalent organic group; n^{A21} is an integer of 2 to 100; and * represents a binding site.

Examples of the aliphatic hydrocarbon group having 1 to 5 carbon atoms represented by R^{A21} to R^{A24} in the general formulae (A2-1) and (A2-2) include alkyl group having 1 to 5 carbon atoms, such as a methyl group, an ethyl group, an n-propyl group, an isopropyl group, an n-butyl group, an isobutyl group, a t-butyl group, and a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and still more preferably a methyl group.

Examples of a substituent of a phenyl group in a substituted phenyl group represented by R^{A21} to R^{A24} include the aliphatic hydrocarbon groups having 1 to 5 carbon atoms.

Examples of the divalent organic group represented by X^{A21} and X^{A22} include an alkylene group, an alkenylene group, an alkynylene group, an arylene group, —O— and a divalent linking group in which they are combined.

Examples of the alkylene group include alkylene groups having 1 to 10 carbon atoms, such as a methylene group, an ethylene group, and a propylene group.

Examples of the alkenylene group include an alkenylene group having 2 to 10 carbon atoms.

Examples of the alkynylene group include an alkynylene group having 2 to 10 carbon atoms.

Examples of the arylene group include arylene groups having 6 to 20 carbon atoms, such as a phenylene group and a naphthylene group.

Among these, X^{A21} and X^{A22} are preferably an alkylene group or an arylene group, and more preferably an alkylene group.

n^{A21} is an integer of 2 to 100, preferably an integer of 2 to 50, more preferably an integer of 3 to 40, and still more preferably an integer of 5 to 30. When n^{A21} is an integer of 2 or more, a plurality of R^{A21}'s or a plurality of R^{A22}'s may be the same as or different from each other.

The siloxane compound (A2) is preferably a polydimethylsiloxane having primary amino groups at both ends, and more preferably a polydimethylsiloxane having primary amino groups only at both ends.

The equivalent of the primary amino groups of the siloxane compound (A2) is not particularly limited, but is preferably 300 to 2,000 g/mol, more preferably 400 to 1,500 g/mol, and still more preferably 500 to 1,000 g/mol.

The weight-average molecular weight (Mw) of the siloxane compound (A2) is not particularly limited, but is preferably 400 to 10,000, more preferably 1,000 to 5,000, still more preferably 1,500 to 4,000, and particularly preferably 2,000 to 3,000, from the viewpoint of handleability and moldability.

### (Method for Producing Siloxane-Modified Maleimide Resin (A))

The siloxane-modified maleimide resin (A) can be produced by, for example, reacting the maleimide resin (A1) with the siloxane compound (A2) in an organic solvent.

When the maleimide resin (A1) is reacted with the siloxane compound (A2), the siloxane-modified maleimide resin (A) obtained by a Michael addition reaction of the N-substituted maleimide groups of the maleimide resin (A1) with the primary amino groups of the siloxane compound (A2) is obtained.

The reaction temperature of the Michael addition reaction is, for example, 50 to 160° C. from the viewpoint of workability, such as a reaction rate, and suppression of gelation of a product in the reaction. Further, the reaction time of the Michael addition reaction is, for example, 0.5 to 10 hours from the viewpoint of productivity and sufficient progression of the reaction.

### (Content of Siloxane-Modified Maleimide Resin (A))

The content of the siloxane-modified maleimide resin (A) in the resin composition of the present embodiment is not particularly limited, but is preferably 20 to 90 mass %, more preferably 30 to 80 mass %, and still more preferably 40 to 70 mass %, with respect to the total amount (100 mass %) of a resin component in the resin composition of the present embodiment.

When the content of the siloxane-modified maleimide resin (A) is equal to or more than the lower limit value, a cured product having more excellent moldability, heat resistance, and adhesion to conductors tends to be easily obtained. Further, when the content of the siloxane-modified maleimide resin (A) is equal to or less than the upper limit value, a cured product having more excellent dielectric characteristics tends to be easily obtained.

In the present description, the “resin component” means a resin and a compound that forms a resin by a curing reaction. For example, the component (A) and the component (B) correspond to the resin component. When the resin composition contains a resin or a compound that forms a resin by a curing reaction as an optional component in addition to the above-mentioned components, the optional component is also contained in the resin component. Examples of the resin component serving as the optional component include a component (E) and a component (F) to be described later. Meanwhile, the component (C), a component (D), and a component (G) are not contained in the resin component.

The content of the resin component in the resin composition of the present embodiment is not particularly limited, but is preferably 20 to 90 mass %, more preferably 30 to 70 mass %, and still more preferably 40 to 60 mass %, with respect to the total amount (100 mass %) of the solid content in the resin composition.

When the content of the resin component is equal to or more than the lower limit value, the moldability of the resin composition tends to be easily improved. When the content of the resin component is equal to or less than the upper limit value, a cured product having more excellent low thermal expansion properties tends to be easily obtained.

### <Polyphenylene Ether-Based Resin (B)>

The polyphenylene ether-based resin (B) is not particularly limited as long as it is a resin having a polyphenylene ether chain and a functional group containing an ethylenically unsaturated bond.

When the resin composition of the present embodiment contains the polyphenylene ether-based resin (B), a cured product having more excellent dielectric characteristics tends to be easily obtained.

One kind of the polyphenylene ether-based resin (B) may be used alone, or two or more kinds thereof may be used in combination.

The polyphenylene ether-based resin (B) has a phenylene ether bond, and preferably has a structural unit represented by the following general formula (B-1).

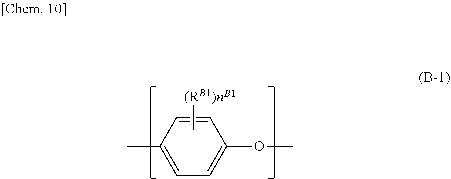

In the formula, R^{B1} is a hydrocarbon group having 1 to 5 carbon atoms or a halogen atom; and n^{B1} is an integer of 0 to 4.

Examples of the hydrocarbon group having 1 to 5 carbon atoms represented by R^{B1} in the general formula (B-1) include a methyl group, an ethyl group, an n-propyl group, an isopropyl group, an n-butyl group, an isobutyl group, a t-butyl group, and an n-pentyl group. The hydrocarbon group having 1 to 5 carbon atoms may be either linear or branched. The hydrocarbon group having 1 to 5 carbon atoms is preferably a hydrocarbon group having 1 to 3 carbon atoms, and more preferably a methyl group.

Examples of the halogen atom include a fluorine atom, a chlorine atom, a bromine atom, and an iodine atom.

n^{B1} in the general formula (B-1) is an integer of 0 to 4, preferably 1 or 2, and more preferably 2. When n^{B1} is 1 or 2, it is preferable that the substitution position of R^{B}1 be an ortho position on the benzene ring with respect to the substitution position of an oxygen atom. When n^{B1} is an integer of 2 or more, a plurality of RBs may be the same as or different from each other.

A phenylene ether unit represented by the general formula (B-1) is preferably a phenylene ether unit represented by the following general formula (B-1′).

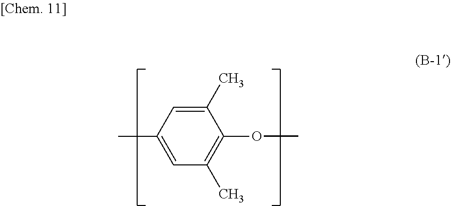

The polyphenylene ether-based resin (B) has a functional group containing an ethylenically unsaturated bond (hereinafter sometimes referred to as “ethylenically unsaturated bond-containing group”).

In the present description, the “ethylenically unsaturated bond” means a carbon-carbon double bond capable of an addition reaction, and does not contain a double bond of an aromatic ring.

Examples of the ethylenically unsaturated bond-containing group include a vinyl group, an allyl group, a 1-methylally group, an isopropenyl group, a 2-butenyl group, a 3-butenyl group, a styryl group, a maleimide group, and a group represented by the following general formula (B-2).

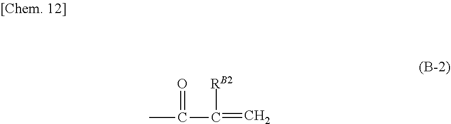

In the formula, R^{B2} is a hydrogen atom or an alkyl group having 1 to 20 carbon atoms.

The number of carbon atoms in the alkyl group having 1 to 20 carbon atoms represented by R^{B2} in the general formula (B-2) is preferably 1 to 10, more preferably 1 to 3, and still more preferably 1. That is, R^{B2} is still more preferably a methyl group. The group represented by the general formula (B-2) in which R^{B2} is a hydrogen atom corresponds to an acryloyl group, and the group represented by the general formula (B-2) in which R^{B2} is a methyl group corresponds to a methacryloyl group.

Among the above-mentioned groups, from the viewpoint of dielectric characteristics, the ethylenically unsaturated bond-containing group of the polyphenylene ether-based resin (B) is preferably a group represented by the general formula (B-2), more preferably a (meth)acryloyl group, and still more preferably a methacryloyl group.

The number of the ethylenically unsaturated bond-containing group in one molecule of the polyphenylene ether-based resin (B) is not particularly limited, but is preferably 1 to 5, more preferably 2 to 3, and still more preferably 2.

When the number of the ethylenically unsaturated bond-containing group is equal to or more than the lower limit value, a cured product having more excellent heat resistance tends to be easily obtained. Further, when the number of the ethylenically unsaturated bond-containing group is equal to or less than the upper limit value, the flowability and the moldability of the resin composition tends to be easily improved.

The polyphenylene ether-based resin (B) preferably has the ethylenically unsaturated bond-containing group at an end, and more preferably has the ethylenically unsaturated bond-containing group at both ends.

The polyphenylene ether-based resin (B) may have the ethylenically unsaturated bond-containing group at a moiety other than the end, but preferably has the ethylenically unsaturated bond-containing group only at the end, and more preferably has the ethylenically unsaturated bond-containing group only at both ends.

The weight-average molecular weight (Mw) of the polyphenylene ether-based resin (B) is preferably 500 to 7,000, more preferably 800 to 5,000, and still more preferably 1,000 to 3,000.

When the weight-average molecular weight (Mw) of the polyphenylene ether-based resin (B) is equal to or more than the lower limit value, a cured product having excellent dielectric characteristics and heat resistance tends to be easily obtained. Further, when the weight-average molecular weight (Mw) of the polyphenylene ether-based resin (B) is equal to or less than the upper limit value, the moldability of the resin composition tends to be easily improved.

To a method for synthesizing the polyphenylene ether-based resin (B), a known method for synthesizing or modifying a polyphenylene ether can be applied, and the method is not particularly limited.

### (Content of Polyphenylene Ether-Based Resin (B))

The content of the polyphenylene ether-based resin (B) in the resin composition of the present embodiment is not particularly limited, but is preferably 1 to 30 mass %, more preferably 5 to 25 mass %, and still more preferably 10 to 20 mass %, with respect to the total amount (100 mass %) of the resin component in the resin composition of the present embodiment.

When the content of the polyphenylene ether-based resin (B) is equal to or more than the lower limit value, a cured product having excellent dielectric characteristics tends to be easily obtained. Further, when the content of the polyphenylene ether-based resin (B) is equal to or less than the upper limit value, the moldability of the resin composition tends to be easily improved.

### <Phosphorus-Based Flame Retardant Containing Phosphorus Atom in Content of 12 Mass % or More (C)>

The phosphorus-based flame retardant (C) is not particularly limited as long as the content of a phosphorus atom is 12 mass % or more. A metal salt of phosphoric acid is preferred, and a metal salt of disubstituted phosphinic acid is more preferred.

Examples of the metal salt of disubstituted phosphinic acid include a metal salt of dialkylphosphinic acid, a metal salt of diallylphosphinic acid, a metal salt of divinylphosphinic acid, and a metal salt of diarylphosphinic acid.

Examples of the metal salt of disubstituted phosphinic acid include a lithium salt, a sodium salt, a potassium salt, a calcium salt, a magnesium salt, an aluminum salt, a titanium salt, and a zinc salt. Among these, an aluminum salt is preferred, and aluminum trisdiethylphosphate is more preferred.

One kind of the phosphorus-based flame retardant (C) may be used alone, or two or more kinds thereof may be used in combination.

The content of a phosphorus atom in the phosphorus-based flame retardant (C) is 12 mass % or more. The phosphorus-based flame retardant (C) in which the content of a phosphorus atom is 12 mass % or more can achieve excellent circuit embedding properties while the resin flow of the resin composition is satisfactorily suppressed.

From the same viewpoint, the content of a phosphorus atom in the component (C) is preferably 13 to 50 mass %, more preferably 15 to 40 mass %, and still more preferably 20 to 30 mass %.

### (Content of Phosphorus-Based Flame Retardant (C))

The content of the phosphorus-based flame retardant (C) in the resin composition of the present embodiment is not particularly limited, but is preferably 1 to 30 parts by mass, more preferably 3 to 20 parts by mass, and still more preferably 4 to 10 parts by mass, with respect to the total amount (100 parts by mass) of the resin component in the resin composition of the present embodiment.

When the content of the phosphorus-based flame retardant (C) is equal to or more than the lower limit value, the flame resistance, the resin flow, and the circuit embedding properties tend to be easily improved.

The content of the phosphorus-based flame retardant (C) in the resin composition of the present embodiment is not particularly limited, but is preferably 0.5 to 15 mass %, more preferably 1 to 10 mass %, and still more preferably 2 to 5 mass %, with respect to the total amount (100 mass %) of the solid content in the resin composition of the present embodiment.

When the content of the phosphorus-based flame retardant (C) is equal to or more than the lower limit value, the flame resistance, the resin flow, and the circuit embedding properties tend to be easily improved.

### <Inorganic Filler (D)>

It is preferable that the resin composition of the present embodiment further contains an inorganic filler (D).

When the resin composition of the present embodiment contains the inorganic filler (D), a cured product having more excellent low thermal expansion properties, heat resistance, and flame resistance tend to be easily obtained.

One kind of the inorganic filler (D) may be used alone, or two or more kinds thereof may be used in combination.

Examples of the inorganic filler (D) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among these, from the viewpoint of low thermal expansion properties, heat resistance, and flame resistance, silica, alumina, mica, and talc are preferred, silica and alumina are more preferred, and silica is still more preferred. From the viewpoint of dispersibility and moldability, molten silica is preferred as silica.

The average particle diameter of the inorganic filler (D) is not particularly limited, but is preferably 0.01 to 20 μm, more preferably 0.1 to 10 μm, still more preferably 0.2 to 1 μm, and particularly preferably 0.3 to 0.8 μm, from the viewpoint of dispersibility of the inorganic filler (D) and formation of fine wiring.

In the present description, the average particle diameter of the inorganic filler (D) represents a particle diameter at a position corresponding to a volume of 50% in a cumulative frequency distribution curve of particle diameter determined when the whole volume of particles is 100%. The average particle diameter of the inorganic filler (D) can be measured, for example, with a particle size distribution measuring device using a laser diffraction and scattering method. The shape of the inorganic filler (D) is, for example, a spherical shape, a crushed shape, or the like, and a spherical shape is preferred.

### (Content of Inorganic Filler (D))

When the resin composition of the present embodiment contains the inorganic filler (D), the content of the inorganic filler (D) is not particularly limited, but is preferably 20 to 90 mass %, more preferably 30 to 70 mass %, and still more preferably 40 to 60 mass %, with respect to the total amount (100 mass %) of the solid content in the resin composition.

When the content of the inorganic filler (D) is equal to or more than the lower limit value, a cured product having more excellent low thermal expansion properties, heat resistance, and flame resistance tends to be easily obtained. Further, when the content of the inorganic filler (D) is equal to or less than the upper limit value, the moldability of the resin composition tends to be easily improved.

### <Maleimide Resin (E)>

It is preferable that the resin composition of the present embodiment further contains a maleimide resin (E).

One kind of the maleimide resin (E) may be used alone, or two or more kinds thereof may be used in combination.

Examples of the maleimide resin (E) are the same as the examples of the maleimide resin (A1) described in section <Siloxane-modified Maleimide Resin (A)>.

### (Content of Maleimide Resin (E))

When the resin composition of the present embodiment contains the maleimide resin (E), the content of the maleimide resin (E) in the resin composition of the present embodiment is not particularly limited, but is preferably 5 to 40 mass %, more preferably 10 to 30 mass %, and still more preferably 15 to 25 mass %, with respect to the total amount (100 mass %) of the resin component in the resin composition of the present embodiment.

When the content of the maleimide resin (E) is equal to or more than the lower limit value, a cured product having more excellent moldability, heat resistance, and adhesion to conductors tends to be easily obtained. Further, when the content of the maleimide resin (E) is equal to or less than the upper limit value, a cured product having more excellent dielectric characteristics tends to be easily obtained.

### <Styrene-based Elastomer (F)>

It is preferable that the resin composition of the present embodiment further contains a styrene-based elastomer (F).

When the resin composition of the present embodiment contains the styrene-based elastomer (F), the dielectric characteristics tend to be improved.

One kind of the styrene-based elastomer (F) may be used alone, or two or more kinds thereof may be used in combination.

The styrene-based elastomer (F) has a structural unit derived from a styrene-based compound (hereinafter sometimes referred to as “styrene-based unit”).

Examples of the styrene-based compound include styrene; and alkyl-substituted styrenes, such as α-methylstyrene, o-methylstyrene, m-methylstyrene, and p-methylstyrene. The number of carbon atoms of an alkyl group of the alkyl-substituted styrene is preferably 1 to 5, more preferably 1 to 3, and still more preferably 1 or 2.

The styrene-based elastomer (F) may contain a structural unit other than the styrene-based unit.

Examples of the structural unit other than the styrene-based unit include a structural unit derived from butadiene, a structural unit derived from isoprene, a structural unit derived from maleic acid, and a structural unit derived from maleic anhydride. The structural unit derived from butadiene and the structural unit derived from isoprene may be hydrogenated. When the structural unit is hydrogenated, the structural unit derived from butadiene is a structural unit in which an ethylene unit and a butylene unit are mixed, and the structural unit derived from isoprene is a structural unit in which an ethylene unit and a propylene unit are mixed.

Examples of the styrene-based elastomer (F) include a hydrogenated product of a styrene-butadiene-styrene block copolymer, a hydrogenated product of a styrene-isoprene-styrene block copolymer, and a styrene-maleic anhydride copolymer.

Examples of the hydrogenated product of a styrene-butadiene-styrene block copolymer include SEBS in which a carbon-carbon double bond in a butadiene block is completely hydrogenated and SBBS in which a carbon-carbon double bond at a 1,2-binding moiety in a butadiene block is partially hydrogenated. The hydrogenated product of a styrene-isoprene-styrene block copolymer is obtained as SEPS in which a polyisoprene moiety is hydrogenated. Among these, from the viewpoint of dielectric characteristics, adhesion to conductors, heat resistance, glass transition temperature, and low thermal expansion properties, SEBS and SEPS are preferred, and SEBS is more preferred.

From the viewpoint of dielectric characteristics, adhesion to conductors, heat resistance, and low thermal expansion properties, the content ratio of the styrene-based unit in the styrene-based elastomer (F) (hereinafter sometimes referred to as “styrene content ratio”) is preferably 5 to 60 mass %, more preferably 7 to 40 mass %, and still more preferably 10 to 20 mass %.

The styrene-based elastomer (F) may be obtained by acid modification with maleic anhydride or the like. The acid value of the acid-modified styrene-based elastomer (F) is preferably 2 to 20 mgCH₃ONa/g, more preferably 5 to 15 mgCH₃ONa/g, and still more preferably 7 to 13 mgCH₃ONa/g.

The number-average molecular weight (Mn) of the styrene-based elastomer (F) is preferably 10,000 to 500,000, more preferably 50,000 to 350,000, and still more preferably 100,000 to 200,000.

When the resin composition of the present embodiment contains the styrene-based elastomer (F), the content of the styrene-based elastomer (F) in the resin composition of the present embodiment is preferably 1 to 30 mass %, more preferably 3 to 20 mass %, and still more preferably 5 to 10 mass %, with respect to the total amount (100 mass %) of the resin component in the resin composition.

When the content of the styrene-based elastomer (F) is equal to or more than the lower limit value, the dielectric characteristics tend to be easily improved. Further, when the content of the styrene-based elastomer (F) is equal to or less than the upper limit value, the heat resistance and the flame resistance tend to be easily improved.

### <Curing Accelerator (G)>

It is preferable that the resin composition of the present embodiment further contains a curing accelerator (G).

When the resin composition of the present embodiment contains the curing accelerator (G), the curing properties are improved, and the dielectric characteristics, the heat resistance, and the adhesion to conductors tend to be easily improved.

One kind of the curing accelerator (G) may be used alone, or two or more kinds thereof may be used in combination.

Examples of the curing accelerator (G) include acidic catalysts, such as p-toluenesulfonic acid; amine compounds, such as triethylamine, tributylamine, pyridine, and dicyandiamide; imidazole compounds, such as methylimidazole, phenylimidazole, 2-undecylimidazole, 1-cyanoethyl-2-phenylimidazole, and 1-cyanoethyl-2-phenylimidazolium trimellitate; isocyanate-masked imidazole compounds, such as an addition reaction product of hexamethylene diisocyanate resin and 2-ethyl-4-methylimidazole; a quaternary ammonium compound; phosphorus-based compounds, such as triphenylphosphine, and a quaternary phosphonium compound that is an addition reaction product of p-benzoquinone and tri-n-butylphosphine; organic peroxides, such as dicumyl peroxide, 2,5-dimethyl-2,5-bis(t-butylperoxy)hexine-3, 2,5-dimethyl-2,5-bis(t-butylperoxy)hexane, t-butylperoxy isopropyl monocarbonate, and α,α′-bis(t-butylperoxy)diisopropylbenzene; inorganic peroxides, such as potassium persulfate, sodium persulfate, and ammonium persulfate; azo compounds, such as 2,2′-azobisisobutyronitrile, 2,2′-azobis(2,4-dimethylvaleronitrile), and 2,2′-azobis(4-methoxy-2′-dimethylvaleronitrile); carboxylate salts of manganese, cobalt, and zinc; and acidic catalysts, such as p-toluenesulfonic acid.

Among these, from the viewpoint of a curing accelerating effect and storage stability, an organic peroxide, an imidazole compound, and a phosphorus-based compound are preferred, and the combination use thereof is more preferred.

When the resin composition of the present embodiment contains the curing accelerator (G), the content of the curing accelerator (G) is preferably 0.01 to 10 parts by mass, more preferably 0.1 to 7 parts by mass, and still more preferably 0.5 to 5 parts by mass, with respect to the total amount (100 parts by mass) of the resin component in the resin composition of the present embodiment.

When the content of the curing accelerator (G) is equal to or more than the lower limit value, a sufficient curing accelerating effect tends to be easily achieved. Further, when the content of the curing accelerator (G) is equal to or less than the upper limit value, the storage stability tends to be easily improved.

### <Other Components>

The resin composition of the present embodiment may further contain one or more selected from the group consisting of a resin material other than the above-mentioned components, an antioxidant, a thermal stabilizer, an antistat, an ultraviolet absorber, a pigment, a colorant, a lubricant, and other additives as required. One kind of each of the other components may be used alone, or two or more kinds thereof may be used in combination. The usage amount of each of the other components is not particularly limited, and each of the other components may be used within a range that does not impair the effects of the present embodiment as required.

### (Organic Solvent)

From the viewpoint of facilitating handling and from the viewpoint of facilitating the production of a prepreg to be described later, the resin composition of the present embodiment may contain an organic solvent.

One kind of the organic solvent may be used alone, or two or more kinds thereof may be used in combination.

Examples of the organic solvent include alcoholic solvents, such as ethanol, propanol, butanol, methyl cellosolve, butyl cellosolve, and propylene glycol monomethyl ether; ketone-based solvents, such as acetone, methyl ethyl ketone, methyl isobutyl ketone, and cyclohexanone; ether-based solvents, such as tetrahydrofuran; aromatic hydrocarbon-based solvents, such as toluene, xylene, and mesitylene; nitrogen atom-containing solvents, such as dimethylformamide, dimethylacetamide, and N-methylpyrrolidone; sulfur atom-containing solvents, such as dimethylsulfoxide; and ester-based solvents, such as y-butyrolactone.

Among these, from the viewpoint of solubility, an alcoholic solvent, a ketone-based solvent, a nitrogen atom-containing solvent, and an aromatic hydrocarbon-based solvent are preferred, a ketone-based solvent is more preferred, and methyl ethyl ketone is still more preferred.

### <Method for Producing Resin Composition>

The resin composition of the present embodiment can be produced by mixing the components by a known method. In this case, the respective components may be dissolved or dispersed while stirring. Conditions, such as a mixing order, a temperature, and a time, are not particularly limited, and may be optionally set according to the kinds of raw materials, or the like.

### [Prepreg]

A prepreg of the present embodiment is a prepreg containing the resin composition of the present embodiment or a semi-cured product of the resin composition.

The prepreg of the present embodiment contains, for example, the resin composition of the present embodiment or a semi-cured product of the resin composition and a sheet-shaped fiber base material.

As the sheet-shaped fiber base material contained in the prepreg of the present embodiment, for example, known sheet-shaped fiber base materials used in various laminates for electrical insulating materials can be used.

Examples of a material for the sheet-shaped fiber base material include inorganic fibers, such as E glass, D glass, S glass, and Q glass; organic fibers, such as polyimide, polyester, and tetrafluoroethylene; and mixtures thereof. The sheet-shaped fiber base materials have a shape of, for example, a woven fabric, a nonwoven fabric, a roving, a chopped strand mat, or a surfacing mat.

The prepreg of the present embodiment can be produced by, for example, impregnating or coating the sheet-shaped fiber base material with the resin composition of the present embodiment, and then heating and drying the resin composition resulting in B-staging.

A temperature and a time of the heating and drying are not particularly limited, and from the viewpoint of productivity and appropriate B-staging of the resin composition of the present embodiment, for example, the temperature and the time can be set to 50 to 200° C. and 1 to 30 minutes, respectively.

The content of the resin composition in the prepreg of the present embodiment is not particularly limited, and from the viewpoint of easily obtaining more satisfactory moldability when a laminate is formed, the content is preferably 20 to 90 mass %, more preferably 40 to 85 mass %, and still more preferably 50 to 80 mass %.

### [Resin Film]

A resin film of the present embodiment is a resin film containing the resin composition of the present embodiment or a semi-cured product of the resin composition.

The resin film of the present embodiment can be produced by, for example, applying the resin composition of the present embodiment containing an organic solvent to a support and then heating and drying the resin composition.

Examples of the support include a plastic film, a metal foil, and a release paper.

A heating and drying temperature and a time are not particularly limited, but from the viewpoint of productivity and appropriate B-staging of the resin composition of the present embodiment, the temperature and the time can be set to 50 to 200° C. and 1 to 30 minutes, respectively.

The resin film of the present embodiment is preferably used for forming an insulating layer in the case of producing a printed wiring board.

### [Laminate]

A laminate of the present embodiment is a laminate including a cured product of the resin composition of the present embodiment, and a metal foil.

A laminate including a metal foil is sometimes referred to as a metal-clad laminate.

A metal of the metal foil is not particularly limited, and examples thereof include copper, gold, silver, nickel, platinum, molybdenum, ruthenium, aluminum, tungsten, iron, titanium, chromium, and an alloy containing one or more of these metal elements.

The laminate of the present embodiment can be produced by, for example, disposing a metal foil on one surface or both surfaces of the prepreg of the present embodiment, and then performing heating and press molding.

Usually, the B-staged prepreg is cured by the heating and press molding, to obtain the laminate of the present embodiment.

When heating and press molding are performed, only one sheet of the prepreg may be used, or two or more sheets of the prepreg may be laminated and used.

For the heating and press molding, for example, a multi-stage press, a multi-stage vacuum press, continuous molding, an autoclave molding machine, or the like can be used.

The conditions of the heating and press molding are not particularly limited, and, for example, the temperature may be 100 to 300° C., the time may be 10 to 300 minutes, and the pressure may be 1.5 to 5 MPa.

### [Printed Wiring Board]

A printed wiring board of the present embodiment is a printed wiring board including a cured product of the resin composition of the present embodiment.

The printed wiring board of the present embodiment can be produced by, for example, performing conductor circuit formation by a known method on one or more selected from the group consisting of a cured product of the prepreg of the present embodiment, a cured product of the resin film of the present embodiment, and the laminate. In addition, a multilayered printed wiring board can also be produced by further performing a multilayering adhesion process as required. A conductor circuit can be formed by, for example, appropriately performing a drilling process, a metal plating process, etching of the metal foil, or the like.

### [Semiconductor Package]

A semiconductor package of the present embodiment is a semiconductor package including the printed wiring board of the present embodiment and a semiconductor element.

The semiconductor package of the present embodiment can be produced by, for example, mounting a semiconductor chip, a memory, and the like on the printed wiring board of the present embodiment by a known method.

### EXAMPLES

Hereinafter, the present embodiment will be specifically described with reference to Examples. However, the present embodiment is not limited to the following Examples.

In each example, a weight-average molecular weight (Mw) was measured by the following method.

The weight-average molecular weight was determined from a calibration curve using standard polystyrene by gel permeation chromatography (GPC). The calibration curve was approximated by a cubic equation using standard polystyrene: TSKstandard POLYSTYRENE (Type: A-2500, A-5000, F-1, F-2, F-4, F-10, F-20, and F-40) (manufactured by Tosoh Corporation, product name). The measurement conditions of GPC are shown below.
Device:
   Pump: L-6200 type (manufactured by Hitachi High-Technologies Corporation)
   Detector: L-3300 type RI (manufactured by Hitachi High-Technologies Corporation)
   Column oven: L-655A-52 (manufactured by Hitachi High-Technologies Corporation)
   Column: guard column: TSK Guardcolumn HHR-L+column: TSKgel G4000HHR+TSKgel G2000HHR (all manufactured by Tosoh Corporation, product name) Column size: 6.0×40 mm (guard column), 7.8×300 mm (column)
Eluent: tetrahydrofuran
Sample concentration: 30 mg/5 mL
Injection volume: 20 μL
Flow rate: 1.00 mL/min
Measurement temperature: 40° C.

### Production Example 1: Production of Siloxane-Modified Maleimide Resin

Into a 5 L heatable and coolable reactor equipped with a thermometer, a stirrer, and a moisture content measuring device with a reflux condenser, 100 parts by mass of 2,2-bis[4-(4-maleimidophenoxy)phenyl]propane, 5.6 parts by mass of a silicone compound having primary amino groups at both ends (primary amino group equivalent: 750 g/mol), 7.9 parts by mass of 3,3′-diethyl-4,4′-diaminodiphenylmethane, and 171 parts by mass of propylene glycol monomethyl ether were put and allowed to react with each other for 2 hours under reflux. This product was concentrated at a reflux temperature over 3 hours to produce a solution of siloxane-modified maleimide resin having a solid content concentration of 65 mass %. The weight-average molecular weight (Mw) of the resultant siloxane-modified maleimide resin was about 2,700.

### Examples 1 to 5 and Comparative Examples 1 to 5

### (Production of Resin Composition)

Components shown in Table 1 were stirred and mixed at room temperature with methyl ethyl ketone in accordance with a blending composition shown in Table 1 to prepare a resin composition having a solid content concentration of 55 mass %. In Table 1, the unit of blending amount of each of the components is part by mass, and in the case of a solution, it means part by mass in terms of solid content.

### (Production of Prepreg)

The resin composition obtained in the foregoing was applied to a glass cloth with a thickness of 0.02 mm and then dried at a drying temperature shown in Table 1 for 5 minutes to produce a prepreg. The content of the resin composition in the prepreg obtained in each example is shown in Table 1.

### [Evaluation Method]

Each evaluation was performed in accordance with the following method. The results are shown in Table 1.

### (Method for Evaluating Resin Flow)

Resin flow was evaluated by the following method in accordance with IPC TM-650 method.

After the prepreg obtained in each example was cut into a 102 mm square, four sheets of the prepreg were laminated to obtain a test piece, and the weight of the test piece was measured. The measured weight was represented by W1.

Next, the test piece was placed in a pressing machine in which the temperature, the pressure, and the time was set to 171±3° C., 1.38±0.07 MPa, and 5±0.5 minutes, respectively, and pressed. After that, the test piece was punched from a central portion thereof into a disk with a diameter of 81.1 mm, and the weight was measured. The measured weight was represented by W2.

The resin flow was calculated by the following equation using W1 and W2 obtained in the foregoing.

$$Resin flow ( \% ) = \{ [ W 1 - 2 \times W 2 ] / W 1 \} \times 100$$

### (Method for Evaluating Circuit Embedding Properties)

On a circuit substrate having a circuit for embedding test (thickness: 12 μm, six rectangular regions that each have a pattern of dot-like openings, a copper residual ratio of 50 volume %, and a size of 70 mm by 115 mm are arranged in two rows and three columns through a slit having a width of 2 mm), the prepreg obtained in the foregoing and a copper foil were disposed in this order, and press molding was performed under the following conditions.

### <Press Molding Conditions>

Heating temperature (maximum temperature): 230° C.
Press pressure: 3 MPa
Press time: 3 hours

After press molding, the copper foil on both surfaces was removed by etching, the vicinity of the circuit was observed visually and with a fluorescent microscope, and the circuit embedding properties of the prepreg were evaluated in accordance with the following criteria.
A: There is no part not embedded in a circuit pattern and a slit.
B: There is no part not embedded in a circuit pattern, but there is a part not embedded in a slit.
C: There is a part not embedded in both a circuit pattern and a slit.

TABLE 1
Table 1

| | | | Example | | | | |
|---|---|---|---|---|---|---|---|
| | | | 1 | 2 | 3 | 4 | 5 |
| Blending | Component | Siloxane-modified maleimide resin | 27.9 | 27.9 | 27.9 | 27.9 | 27.9 |
| composition | (A) | | | | | | |
| (part by | Component | Polyphenylene ether-based resin having | 7.2 | 7.2 | 7.2 | 7.2 | 7.2 |
| mass) of resin | (B) | methacryloyl group | | | | | |
| composition | Component | Phosphorus-based flame retardant 1 | 3.2 | 3.2 | 3.2 | 3.2 | 3.2 |
| | (C) | (phosphorus atom content: 23.5 mass %) | | | | | |
| | Comparison | Phosphorus-based flame retardant 2 | | | | | |
| | component | (phosphorus atom content: 8.1 mass %) | | | | | |
| | Component | Silica | 47.4 | 47.4 | 47.4 | 47.4 | 47.4 |
| | (D) | | | | | | |
| | Component | Maleimide resin | 9.7 | 9.7 | 9.7 | 9.7 | 9.7 |
| | (E) | | | | | | |
| | Component | SEBS | 3.4 | 3.4 | 3.4 | 3.4 | 3.4 |
| | (F) | | | | | | |
| | Component | α,α′-di(t-butylperoxy)diisopropylbenzene | 0.5 | 0.5 | 0.5 | 0.5 | 0.5 |
| | (G) | 2-undecylimidazole | 0.2 | 0.2 | 0.2 | 0.2 | 0.2 |
| | | Tri-n-butylphosphine addition reaction | 0.2 | 0.2 | 0.2 | 0.2 | 0.2 |
| | | product of p-benzoquinone | | | | | |
| Drying temperature (° C.) during production of prepreg | | | 145 | 155 | 165 | 155 | 165 |
| Content (mass %) of resin composition in prepreg | | | 66 | 66 | 67 | 76 | 76 |
| Evaluation | Resin flow (%) | | 4 | 5 | 4 | 6 | 5 |
| result | Circuit embedding properties | | A | A | A | A | A |
| | | | Comparative Example | | | | |
| | | | 1 | 2 | 3 | 4 | 5 |
| Blending | Component | Siloxane-modified maleimide resin | 19.2 | 19.2 | 19.2 | 19.2 | 19.2 |
| composition | (A) | | | | | | |
| (part by | Component | Polyphenylene ether-based resin having | 5.0 | 5.0 | 5.0 | 5.0 | 5.0 |
| mass) of resin | (B) | methacryloyl group | | | | | |
| composition | Component | Phosphorus-based flame retardant 1 | | | | | |
| | (C) | (phosphorus atom content: 23.5 mass %) | | | | | |
| | Comparison | Phosphorus-based flame retardant 2 | 12.6 | 12.6 | 12.6 | 12.6 | 12.6 |
| | component | (phosphorus atom content: 8.1 mass %) | | | | | |
| | Component | Silica | 52.9 | 52.9 | 52.9 | 52.9 | 52.9 |
| | (D) | | | | | | |
| | Component | Maleimide resin | 6.6 | 6.6 | 6.6 | 6.6 | 6.6 |
| | (E) | | | | | | |
| | Component | SEBS | 2.3 | 2.3 | 2.3 | 2.3 | 2.3 |
| | (F) | | | | | | |
| | Component | α,α′-di(t-butylperoxy)diisopropylbenzene | 0.4 | 0.4 | 0.4 | 0.4 | 0.4 |
| | (G) | 2-undecylimidazole | 0.1 | 0.1 | 0.1 | 0.1 | 0.1 |
| | | Tri-n-butylphosphine addition reaction | 0.1 | 0.1 | 0.1 | 0.1 | 0.1 |
| | | product of p-benzoquinone | | | | | |

| Drying temperature (° C.) during production of prepreg | | 150 | 160 | 170 | 160 | 170 |
|---|---|---|---|---|---|---|
| Content (mass %) of resin composition in prepreg | | 67 | 66 | 66 | 77 | 78 |
| Evaluation | Resin flow (%) | 6 | 4 | 4 | 19 | 21 |
| result | Circuit embedding properties | C | C | C | B | B |

Details of each material shown in Table 1 are as follows.

### [Component (A)]

Siloxane-modified maleimide resin: the siloxane-modified maleimide resin obtained in Production Example 1

### [Component (B)]

Polyphenylene ether-based resin having a methacryloyl group: polyphenylene ether having a methacryloyl group at both ends (weight-average molecular weight (Mw): 1,700)

### [Component (C)]

Phosphorus-based flame retardant 1: aluminum salt of dialkylphosphinic acid, metal salt of di-substituted phosphinic acid, the content of phosphorus atom: 23.5 mass %0

### [Comparison Component]

Phosphorus-based flame retardant 2: 4,4′-biphenylene bis(di-2,6-dimethylphenylphosphate), the content of phosphorus atom: 8.1 mass %

### [Component (D)]

Silica: spherical fused silica having an average particle diameter of 0.5 μm

### [Component (E)]

Maleimide resin: polyphenylmethane maleimide (product name “BMI-2300,” manufactured by Daiwa Kasei Industrial Co., Ltd.)

### [Component (F)]

SEBS: carboxylic acid-modified hydrogenated styrene-butadiene copolymer resin (product name “Tuftec (registered trademark) M1913,” manufactured by Asahi Kasei Chemicals Corporation, styrene content ratio: 30 mass %, acid value: 10 mgCH₃ONa/g)

### [Component (G)]

α,α′-di(t-butylperoxy)diisopropylbenzene
2-undecylimidazole
Tri-n-butylphosphine addition reaction product of p-benzoquinone

As seen from the results shown in Table 1, the prepregs formed from the resin compositions of Examples 1 to 5 of the present embodiment have improved circuit embedding properties while the resin flow is satisfactorily suppressed.

1. A resin composition comprising:
(A) a siloxane-modified maleimide resin containing a structure derived from a maleimide resin having one or more N-substituted maleimide groups (A1) and a structure derived from a siloxane compound having two or more primary amino groups (A2);
(B) a polyphenylene ether-based resin having a functional group containing an ethylenically unsaturated bond; and
(C) a phosphorus-based flame retardant containing a phosphorus atom in a content of 12 mass % or more.

2. The resin composition according to claim 1, wherein the component (C) is a metal salt of phosphoric acid.

3. The resin composition according to claim 1, wherein a content of the component (C) is 1 to 30 parts by mass with respect to a total amount (100 parts by mass) of a resin component in the resin composition.

4. The resin composition according to claim 1, wherein the component (B) has the functional group containing an ethylenically unsaturated bond at an end thereof.

5. The resin composition according to claim 1, wherein the functional group containing an ethylenically unsaturated bond of the component (B) is a (meth)acryloyl group.

6. The resin composition according to claim 1, further comprising an inorganic filler (D).

7. The resin composition according to claim 6, wherein a content of the component (D) is 20 to 90 mass % with respect to a total amount (100 mass %) of a solid content in the resin composition.

8. A prepreg comprising the resin composition according to claim 1 or a semi-cured product of the resin composition.

9. A laminate comprising: a cured product of the resin composition according to claim 1; and a metal foil.

10. A resin film comprising the resin composition according to claim 1 or a semi-cured product of the resin composition.

11. A printed circuit board comprising a cured product of the resin composition according to claim 1.

12. A semiconductor package comprising: the printed circuit board according to claim 1; and a semiconductor element.
